(19) United States
(12) Patent Application Publication
(10) Pub. No.: US 2024/0306319 A1
(43) Pub. Date: Sep. 12, 2024

(54) MULTI-LEVEL JUNCTION BOX FOR INSTALLATION ON SMALL SURFACE AREA

(71) Applicant: Dana Heavy Vehicle Systems Group, LLC, Maumee, OH (US)

(72) Inventors: Jean-Sebastien PLAMONDON, Laval (CA); Guillaume DESOURDY, Terrebonne (CA)

(21) Appl. No.: 18/426,814

(22) Filed: Jan. 30, 2024

Related U.S. Application Data
(60) Provisional application No. 63/489,673, filed on Mar. 10, 2023.

(51) Int. Cl. H05K 5/00; B60R 16/023

(52) U.S. Cl. CPC H05K 5/006; B60R 16/0238

(57) ABSTRACT

A junction box for a vehicle, comprising a multi-level housing. In at least one example, the junction box may comprise a shelf coupled within a housing, the shelf dividing a first level and a second level of the housing.

### CROSS REFERENCE TO RELATED APPLICATION

The present application claims priority to U.S. Provisional Application No. 63/489,673 entitled “MULTI-LEVEL JUNCTION BOX FOR INSTALLATION ON SMALL SURFACE AREA”, filed Mar. 10, 2023. The entire contents of the above-listed application is hereby incorporated by reference for all purposes.

### TECHNICAL FIELD

The present description relates to a junction box with an interior divided into multiple levels, such that the junction box may be more compact for installation purposes. For example, the junction box according to the present disclosure may be installed onto a smaller surface area of a vehicle compared to previous junction boxes.

### BACKGROUND AND SUMMARY

Fully electric vehicles and hybrid electric vehicles may utilize a battery or another form of energy storage device as a power source and one or more electric machines as a prime mover. A junction box may be used in fully electric vehicles (EVs) or hybrid electric vehicles to electrically couple a plurality of electrical components of the vehicle. For example, a junction box may be used to electrically couple and ground an inverter, a charging device, and/or battery. The junction box may enclose a volume and have a surface to which low voltage and high voltage electrical components may be fastened.

The surface area available in an electric vehicle to install a traditional junction box housing conventional components is generally sufficient. However, as power and electrical requirements for EVs or hybrid vehicles increase, the surface area available in such vehicles for mounting a junction box may decrease. Additionally, as vehicles continue to be developed, junction boxes may house unconventional components that are in addition to previously used conventional components, which may increase the volume the junction box occupies and the surface area used to mount the junction box within the vehicle.

In particular, traditional junction boxes are single level boxes. In order to accommodate additional components, a surface area of such single level junction boxes is increased as a size of the single level junction box is increased to accommodate additional components. In some examples, the surface area of single level junction boxes accommodating high voltage and low voltage components may be significantly increased as the junction box is increased in size to sufficiently separate high voltage and low voltage components to prevent uncontrolled discharge of electrical energy or other events that may cause degradation between the high voltage and low voltage components. Thus, it may be difficult to mount single level junction boxes.

Other attempts to address issues around mounting junction boxes include forming the junction box in an unconventional shape. Additionally or alternatively, components typically enclosed by the junction box may be housed externally from the junction box.

However, the inventors herein have recognized potential issues with such systems. For example, molding or forming the junction box into an unconventional shape may result in increase manufacturing time for and complexity of the junction box. Additionally, the complexity of the shape of the junction box may reduce the strength of the housing in certain regions, making the junction box more prone to degradation. The utility of the junction box may also be decreased by using an unconventional shape, such that the junction box may only usable for a specific mounting area in a specific type vehicle. Further, having the junction box be a traditional shape but having components that would typically be enclosed by the junction box instead be positioned on the exterior of the junction box, may result in those components being unprotected by the junction box from mechanical forces or electrical interference.

In one example, the issues described above may be addressed by a junction box comprising multiple levels. For example, the junction box may comprise a first level and a second level separated by a shelf, where low voltage components are positioned on the first level and high voltage components are positioned on the second level.

In this way, the effective volume available to components housed by the junction box may be increased while reducing a footprint of the junction box as compared to previous single level junction boxes. Further, the separation of spaces via multiple levels may provide sufficient separation of the low voltage and high voltage components to avoid degradation.

It should be understood that the summary above is provided to introduce, in simplified form, a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1 schematically depicts a vehicle driveline including an electrical system according to one or more examples of the present disclosure;

FIG. 2 is an illustration of a junction box from a side perspective view;

FIG. 3 is an illustration of the junction box of FIG. 2 from a top view;

FIG. 4 shows an illustration of a housing of the junction box from a top perspective view;

FIG. 5A shows an illustration of a shelf supporting high voltage components isolated from other components from a top perspective view;

FIG. 5B shows an illustration of the shelf from FIG. 5A supported by and housed in the housing of the junction box from a top perspective view;

FIG. 6 shows an illustration of a plurality of additional high voltage components coupled to the housing supporting the shelf from FIG. 5B;

FIG. 7 shows an illustration of a cutaway of the junction box from FIG. 2;

FIG. 8 shows an illustration a housing of the junction box from FIG. 3 from a top view.

### DETAILED DESCRIPTION

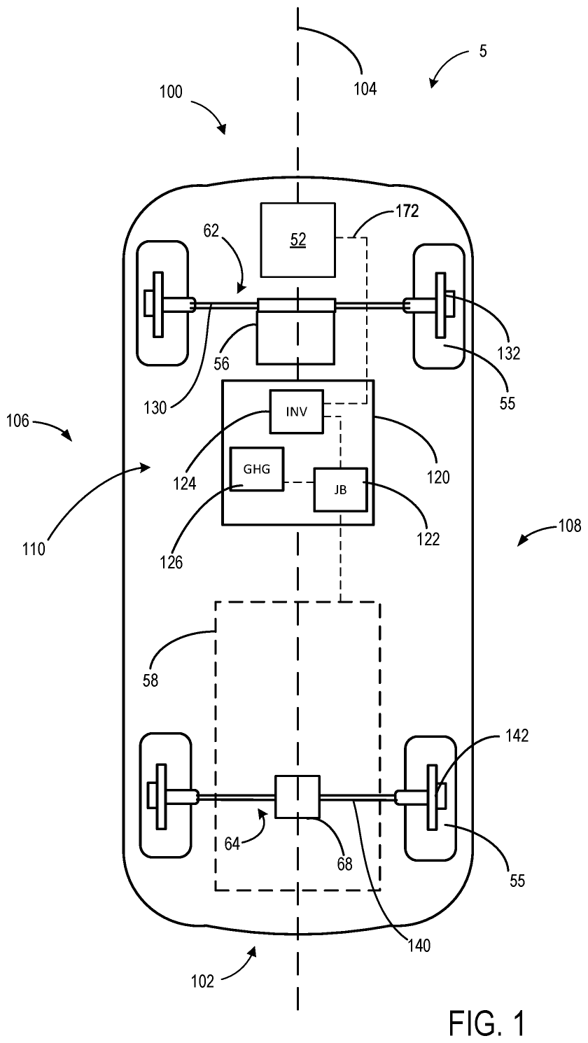

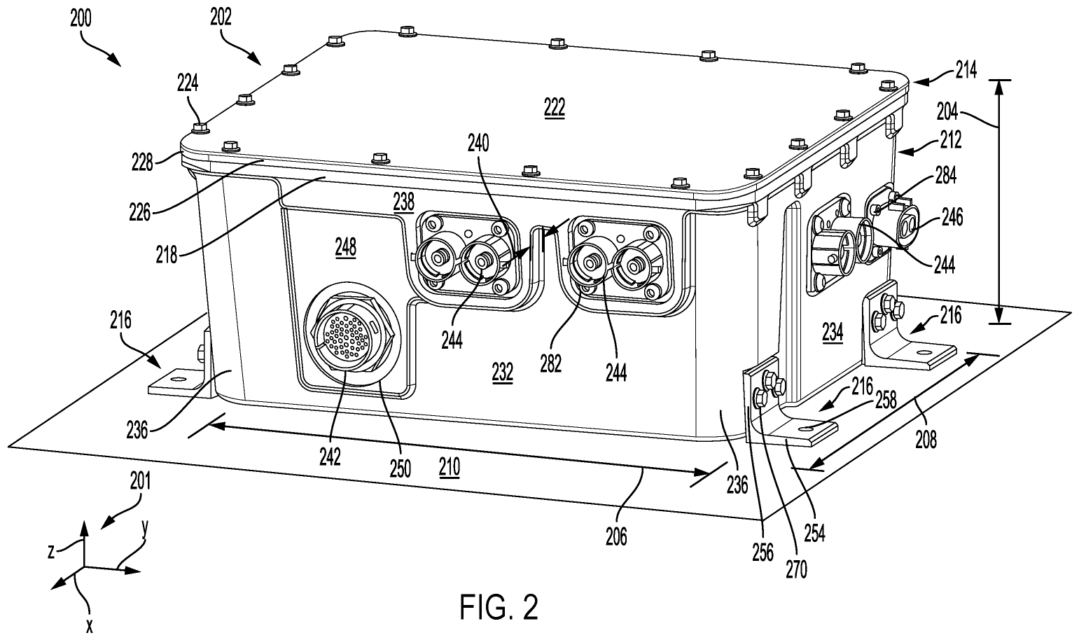

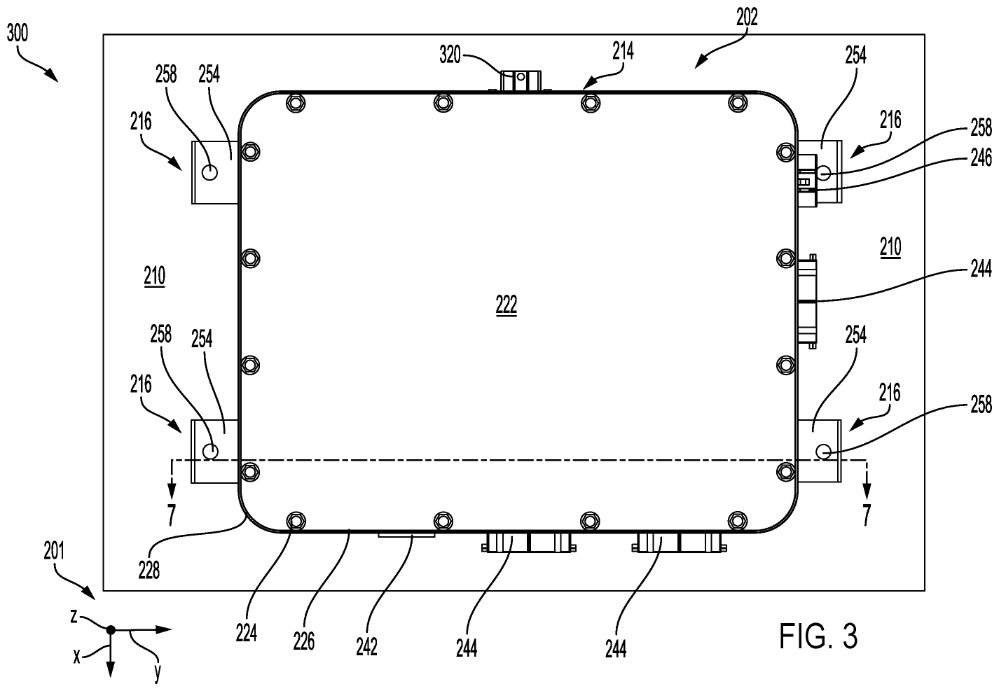

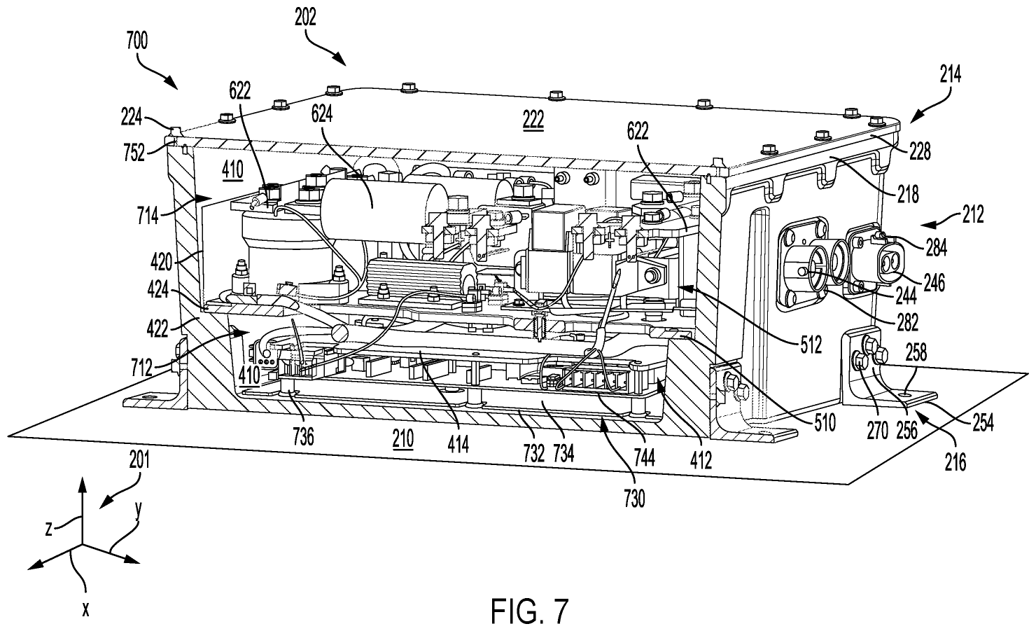

The following description relates to a junction box comprising multiple levels that may be used in fully electric vehicles (EVs) or hybrid electric vehicles, as shown in FIG. 1. The junction box may be formed of a housing and a cover, as illustrated in FIGS. 2-3. Additionally, as shown in FIG. 7, the junction box may further be assembled with and enclose a shelf. The shelf may divide the interior of the junction box into the multiple levels, where a first level includes a first volume and a second level includes a second volume, also referred to as a first space and a second space herein. The first level and second level may be different vertical levels (when the junction box is positioned in its intended orientation within the vehicle) and may house electrical components of different voltage tolerances. For example, one of the spaces may enclose and support components of a higher voltage tolerance, and the other space may enclose and support components of a lower voltage tolerance. Example electrical components may be seen at FIGS. 3-6 and 8. In this way, sufficient space may be provided between the low voltage electrical components and the high voltage electrical components within the junction box, while still maintaining a compact footprint. The technical effect of improved packing and performance may thus be achieved.

It is to be understood that the specific assemblies and systems illustrated in the attached drawings, and described in the following specification are exemplary embodiments of the inventive concepts defined herein. For purposes of discussion, the drawings are described collectively. Thus, like elements may be commonly referred to herein with like reference numerals and may not be re-introduced. FIG. 1 show schematics of example configurations with relative positioning of the various components. FIGS. 2-8 are shown approximately to scale. FIGS. 2A-4B may be used to represent other relative dimensions.

Further, FIGS. 2-8 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. Moreover, the components may be described as they relate to reference axes included in the drawings.

Features described as axial may be approximately parallel with an axis unless otherwise specified. Features described as counter-axial may be approximately perpendicular to an axis unless otherwise specified. Features described as radial may circumferentially surround or extend outward from an axis unless otherwise specified.

Features described as longitudinal may be approximately parallel with an axis that is longitudinal. An axis that is normal to an axis that is longitudinal may be referred to as lateral. Features described as lateral may be approximately parallel with an axis that is lateral.

Turning to FIG. 1, an example vehicle 5 is shown. The vehicle 5 may have a front end 100 and a rear end 102, and may be bisected into approximately symmetrical halves by a longitudinal axis 104. The vehicle 5 may be locating between a first side 106 and a second side 108. The first side 106 and second side 108 are located on opposite sides of the longitudinal axis 104.

In some examples, vehicle 5 may be a hybrid vehicle with multiple sources of torque available to one or more vehicle wheels 55. In other examples, vehicle 5 may be an all-electric vehicle, powered exclusively by an energy storage device 58, such as a battery or a capacitor. The vehicle 5 may for some examples be truck, such as an all-electric truck or a hybrid truck. The vehicle 5 may also be another type of heavy vehicle, such as a tractor or loader.

In the example shown, vehicle 5 includes a prime mover 52. In one example the prime mover 52 may be an electric machine, which may be an electric motor, an electric motor/generator, or an electric motor/engine. For this example, the prime mover 52 may receive electrical power from the energy storage device 58 that is converted to rotational energy, e.g., torque, at a transmission 56. The transmission 56 may include a plurality of reduction sets, such as a gear sets, that may output different rotational speeds and torques with the same input rotational energy from the prime mover 52. The torque may be delivered to vehicle wheels 55, including a set of front wheels proximate to a front end 100 of vehicle 5 and a set of rear wheels proximate to a rear end 102 of vehicle 5. The prime mover 52 may also be operated as a generator to provide electrical power to charge the energy storage device 58.

For other examples the prime mover 52 may be an internal combustion engine (ICE) or a fuel cell, such as a hydrogen fuel cell. In such examples, the vehicle 5 may be a hybrid vehicle, such as a hybrid with an ICE or a hybrid with a fuel cell, and may use a secondary mover that may be an electric machine to provide a hybrid or a fully electric function to the vehicle 5.

The prime mover 52 provides rotational energy to the wheels of vehicle 5 via the transmission 56. The wheels 55 may be drivingly coupled to the vehicle 5 and/or the transmission via a first axle 62 and a second axle 64. For this example, vehicle 5 has the first axle 62 proximate to the front end 100 and the second axle 64 proximate to the rear end 102. For this example, vehicle 5 has the prime mover 52 and the transmission 56 positioned in the front end 100 of vehicle 5. For this example, the prime mover 52 and the transmission 56 may provide rotational energy to a differential 68 to rotate the wheels 55 positioned in the rear end 102 via an implement, such as a drive shaft. It will be appreciated that in other examples, rotational energy may be alternatively provided to the wheels 55 located near the front end 100 of vehicle 5. Furthermore, in other examples, each of the wheels 55 near the front end 100 and the wheels 55 near the rear end 102 may be coupled to individual transmissions, such as when vehicle 5 is configured with all-wheel drive. As well, in other embodiments, transmission 56 and/or prime mover 52 may be arranged closer to the rear end 102 of vehicle 5 rather than the front end 100.

The energy storage device 58 may be positioned between the vehicle wheels 55 and closer to the rear end 102 of vehicle 5 than the front end 100. For example, the energy storage device 58 may be positioned below rear passenger seats of the vehicle. In another example, the energy storage device 58 may be located in a floor of a rear compartment of the vehicle or may be integrated into a vehicle chassis. In other examples, however, the energy storage device 58 may be located in a different relative position within and/or mounted to vehicle 5 than shown in FIG. 1.

The energy storage device 58 and prime mover 52 may be a part of an electrical system 110 electrically coupled to a junction box 122. The electrical system 110 may also include an inverter 124 and a charging device 126. The junction box 122 may distribute and act as a junction for electrical energy from the prime mover 52, energy storage device 58, and other sources of electrical energy, such as a power source electrically coupled to the charging device 126. The prime mover 52 and junction box may be electrically coupled to an inverter 124. The inverter 124 may convert direct current (DC) from the junction box 122 and energy storage device 58 into alternating current (AC) for the prime mover 52, such as when the prime mover 52 is an electric machine. Likewise, AC generated from the prime mover 52 may be converted into DC by the inverter 124 for the junction box 122 and energy storage device 58. Electrical energy from the energy storage device 58, inverter 124, and/or charging device 126 may pass through the junction box 122. For one example, the junction box 122, inverter 124, and charging device 126 may be housed in a housing 120. However, the positioning and configuration of box 122, inverter 124, and/or charging device 126 may be non-limiting. The box 122, inverter 124, and/or charging device 126 may be housed separately of housing 120 when mounted to vehicle 5 and electrically coupled to the electrical system 110. Electrical coupling between components may be represented by a plurality of dashed lines 172.

The wheels 55 proximate to the front end 100 may be drivingly coupled to axle 62 via a shaft 130. The wheels 55 proximate to the front end 100 may be fastened to hubs 132 that may be drivingly coupled shaft 130.

Likewise, wheels 55 proximate to the rear end 102 may be drivingly coupled to axle 64 via a shaft 140. The wheels 55 proximate to the rear end 102 may be fastened to hubs 142 that may be drivingly couple to shaft 140.

A set of reference axes 201 are provided for comparison between views shown in FIG. 2-8. The reference axes 201 indicate a y-axis, an x-axis, and a z-axis. In one example, the z-axis may be parallel with a direction of gravity and the x-y plane may be parallel with a horizontal plane that a junction box 202 may rest upon and a mounting surface may be coplanar with. When referencing direction, positive may refer to in the direction of the arrow of the y-axis, x-axis, and z-axis and negative may refer to in the opposite direction of the arrow of the y-axis, x-axis, and z-axis. A filled circle may represent an arrow and axis facing toward, or positive to, a view. An unfilled circle may represent an arrow and an axis facing away, or negative to, a view.

Turning to FIG. 2, a first view 200 of the junction box 202 is shown. The first view 200 is a side perspective view. The junction box may have a height 204, a length 206, and a width 208. The junction box 202 may rest upon and be supported by a surface 210.

The junction box 202 may be formed by a housing 212 and a cover 214. The cover 214 may be located at and fastened to the top of the housing 212. The cover 214 may be fastened to the housing at a flange 218 formed of the housing 212. The housing 212 may be formed of a material that more easily moldable, such as aluminum. A plurality of mounts 216 may be used to fasten the housing 212 to a surface, such as surface 210. The height 204 of the junction box 202 may be constant. The length 206 and width 208 of the junction box 202 may be variable in one or more examples, wherein the length 206 and width 208 may increase in distance at higher positions with respect to the height 204. The length 206 and width 208 may be of a greatest distance at the cover 214 and flange 218. The length 206 and width 208 may be of a least distance where the housing 212 makes contact with the surface 210. Certain portions and surfaces of the housing 212 may be flush with the cover 214 and flange 218, such as a third surface 238.

The cover 214 of the junction box 202, may have a surface 222 that is approximately or substantially flat. A plurality of first fasteners 224 may fasten the cover 214 of the junction box 202 to the housing 212. The fasteners may extend through and be complementary to a plurality of holes formed in the cover 214 and housing 212. The perimeter 226 of the cover 214 may be located about the first fasteners 224. The perimeter 226 and cover 214 may have a plurality of corners 228. The perimeter 226 and corners 228 may be rounded and beveled. In one or more examples, cover 214 may comprise four corners 228.

The housing 212 may have a plurality of walls that with outward faces form a rectangular prism or box shape. Some of the faces of the walls forming the housing 212 may extend from the perimeter 226 of the cover 214 to the surface 210. For this example, there may be four walls of the housing 212 that may extend from the perimeter 226 of the cover 214 to the surface 210. The walls and sides of the housing 212 may have a plurality of surfaces facing outwardly from the box, such as a first surface 232 and a second surface 234. The first surface 232 and second surface 234 may be connected, or in some examples formed together, by a corner 236. Each wall and each side of the housing 212 may also have a plurality of surfaces. For example, the side with the first surface 232 may also have the third surface 238. The third surface 238 may extend outward from the first surface 232 at a distance 240. Likewise, the cover 214 and the flange 218 may extend outward above the first surface at approximately a distance 240. The corner 236 may be beveled and rounded. There may be a plurality of corners 236 or corners of an approximately similar shape and function located about and formed of the housing of the 212. In one or more examples, there may be four of corners 236 located about and formed from the housing 212. The corners 236 may connect a plurality of other surfaces to the first surface 232 and second surface 234, such that the surfaces about the housing 212 are contiguous.

In at least one example, there may be a surface or surfaces on the opposite side of the housing 212 from the first surface 232 and third surface 238. The surface opposite the first surface 232 and third surface 238 may be contiguous with the second surface 234 via one of corners 236. For this example, there may be a surface or surface on the opposite side of the housing 212 from the second surface 234. The surface or surfaces opposite the second surface 234 may be contiguous with the first and third surfaces 232, 238 via one of corners 236.

The junction box 202 may further comprise a plurality of electrical ports and/or communicative ports, such as a first port 242, second ports 244, and/or a third port 246. The first port 242, the second ports 244, and/or the third port 246 may pass through, be mounted to, and be visible on the surfaces of housing 212. In one or more examples, first port 242 may be concentric to and extend through a hole 250. A depression 248 may be located about the hole 250 and extend into the material of the housing 212. The depression 248 may be located between the first surface 232 and third surface 238. There may be a plurality of second ports 244 mounted to third surface 238 and second surface 234. For this example, there may be three of second ports 244 visible in view 200. Two of the second ports 244 may extend through and be visible on the third surface 238. One of the second ports 244 may extend through and be visible on the second surface 234. There may be one third port 246 visible in first view 200. For this example, the third port 246 may extend through and be visible on the second surface 234. It is to be appreciated that the number and positioning of electrical and/or communicative ports, such as the first port 242, the second ports 244, and third port 246 may be non-limiting. For example, a single or plurality of first ports 242, second ports 244, and third ports 246 may be located on surfaces on the opposite sides of housing 212 from surface 232 and surface 234.

The first port 242 may be used to transfer signals from a component or device external to the junction box 202, such as a controller. When coupled to the first port 242, the aforementioned component or device may be communicatively coupled to electronic components of the junction box 202.

In one or more examples, the junction box 202 may comprise one or more mounts 216 configured to couple the junction box 202 to a vehicle (e.g., vehicle 5). Each of the mounts 216 may be formed of a first mounting section 254 and a second mounting section 256. Each of the first mounting sections 254 may abut and be fastened a mounting surface, such as surface 210, where it is noted that the mounting surface 210 may be a mounting surface within a vehicle. Each of the second mounting sections 256 may abut and be fastened to a surface of the housing 212, such as second surface 234. As such, the first mounting section 254, when the mount 216 is affixed to the surface 210 and the housing 212, may be positioned along an x-y plane, similar to the surface 210, and the second mounting section 256 may be positioned along a plane similar to a surface of the housing 212 to which the mount 216 is affixed (e.g., an x-z plane when affixed to surface 234). In one or more examples, the second mounting sections may abut the surface 234 and corners 236, as well as a surface on the opposite side of housing 212 from surface 234.

Each of the first mounting sections 254 may include a hole 258. The hole 258 may be complementary to a second fastener that may fasten each of the first mounting sections 254 to the surface 210. Each of the second mounting sections 256 may have a plurality of holes. Each of the holes may be complementary to a third fastener 270. There may be a plurality of third fasteners 270 of the same make and type. The third fasteners 270 may fasten each of the second mounting sections 256 to a surface of the housing 212. In one or more examples, there may be a three of the third fasteners 270 and three complementary holes in the second mounting section 256.

The plurality of second fasteners complementary to mounts 216 may be threaded and/or extend through the holes 258 and into complementary holes of the surface 210. The second fasteners may thread or extend through the holes 258 and complementary holes of the surface 210 when the centerlines the holes 258 and centerlines complementary holes of the surface 210 align such that the centerlines are collinear. The plurality of third fasteners 270 may extend through complementary holes in second mounting sections 256 and complementary holes in a surface, such as surface 234, of the housing 212. The third fasteners 270 may thread or extend through the complementary holes in mounting section 256 and a surface of the housing 212 when the centerlines complementary holes of mounting section 256 and a surface of the housing 212 align such that the centerlines are approximately collinear.

The junction box 202 may also have a plurality of fourth fasteners 282 and fifth fasteners 284. The fourth fasteners 282 may be used to fasten the second ports 244 to the housing 212. The fifth fasteners 284 may be used to fasten the third port 246 to the housing 212.

Turning to FIG. 3, a second view 300 of the junction box 202 is shown. The second view 300 is a top-down view. The second view 300 shows the cover 214 and surface 222. The second view 300 shows the cover 214 may have four corners 228.

As shown in the second view 300, the junction box 202 may have a fourth port 320. The fourth port 320 may extend through and be mounted to a wall of the housing 212. In one or more examples, the fourth port 320 may extend through the wall of the housing 212 on the opposite side of the of the junction box 202 from the first surface 232 and third surface 238.

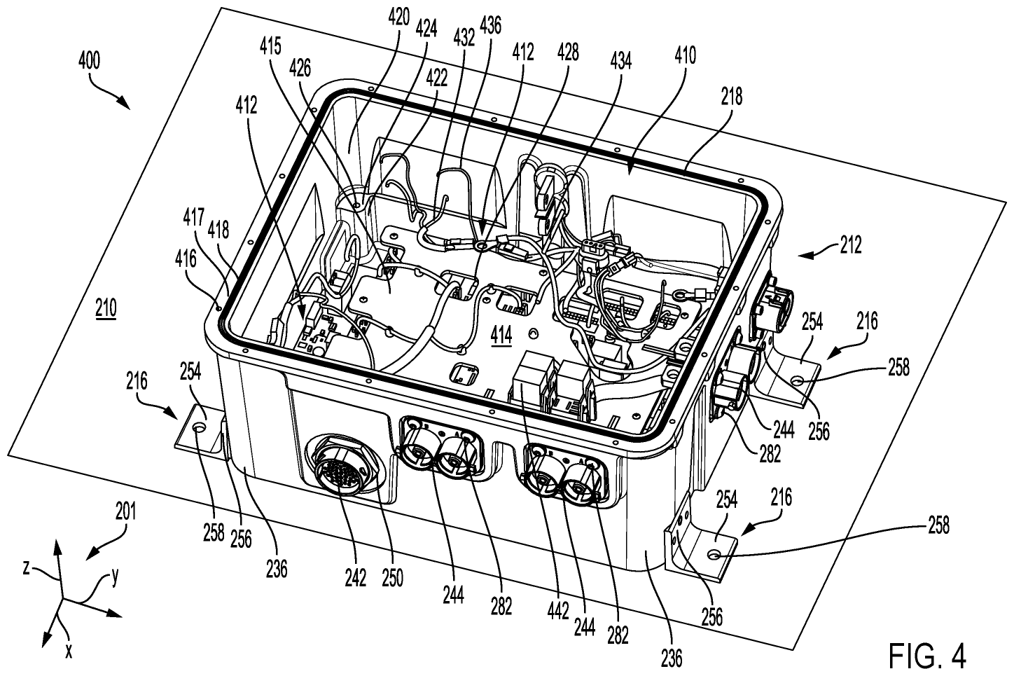

Turning to FIG. 4, a third view 400 of the housing 212 of the junction box 202 is shown. The third view 400 is a top perspective view.

The third view 400 shows an interior 410 of the housing 212. The interior 410 may form a first space that may house a plurality of low voltage components 412, such as contactors, fuses, resistors, a one or more safety switches, relays transducers, current sensors, battery management systems (BMS), and/or the like. The low voltage components 412 may be used for electrical or communicative coupling with components external to the junction box 202. The low voltage components 412 may be fastened or joined to a platform 415. Some of low voltage components 412 may be located vertically below the platform 415. The platform 415 may have a surface 414 that may be substantially or approximately parallel with the surface 210. The surface 414 and platform 415 may act as a cover for the low voltage components 412. The surface 414 may shield low voltage components from a second layer that may support high voltage components. The surface 414 may have a plurality of holes 428 through which wiring may electrically and/or commutatively couple to low voltage components 412 below platform 415.

The third view 400 shows the housing 212 without the cover 214 fastened to the flange 218. The flange 218 is visible, showing a plurality of holes 416 formed from and a bead 418 supported on the top surface 417 of the flange 218. The holes 416 may have a centerline that is and may extend in a direction normal to the top surface 417 through the material of the housing 212. The holes 416 may be complementary to the first fasteners 224. The holes 416 may have a threading complementary to a threading of the first fasteners 224. The through holes 416 may act as the holes of the housing 212 described for FIG. 2. The bead 418 may rest upon and be sealingly coupled to the top surface 417. The bead 418 may extend about the flange 218 and be enclosed by the perimeter of the flange 218.

Each of interior corners 420 may be complementary to one of the corners 236. A plurality of protrusions 422 may be molded and formed from the interior corners 420 and material of the housing 212. Each protrusion 422 may be complementary to one of the interior corners 420.

Each of the protrusions 422 form a surface 424 and a hole 426. The surfaces 424 may act as mounting surfaces to support and abut a second level. The second level may be fastened to the surfaces 424 via fasteners that may extend and/or be threaded through the second level and into the second holes 426. The second holes 426 may be complementary to and have a threading complementary to the aforementioned fasteners.

The wiring of the interior 410 may be cabling, and may include, a plurality of first wires 432, a plurality of second wires 434, plurality of third wires 436, and fourth wires 438. The plurality first wires 432, second wires 434, third wires 436, and fourth wires 438 of may electrically and/or communicatively couple components of the low voltage components 412.

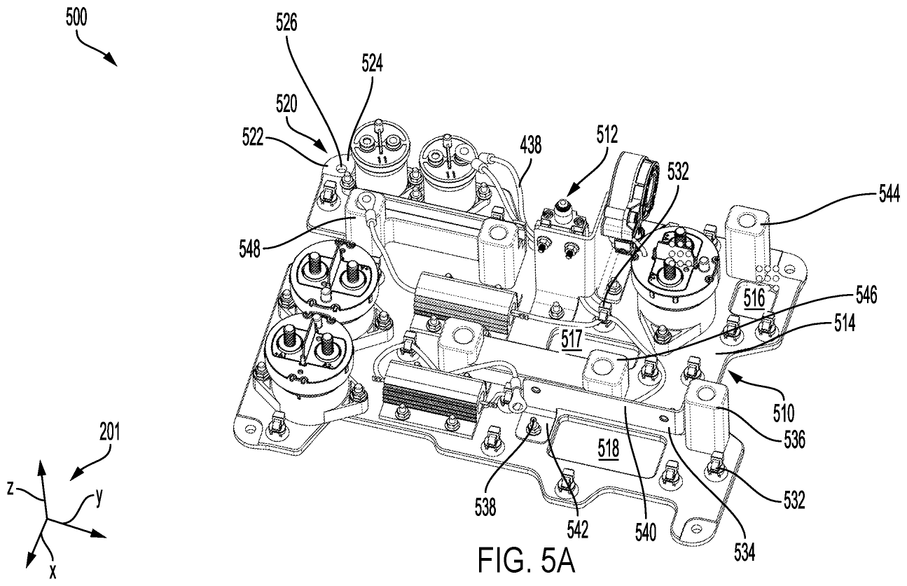

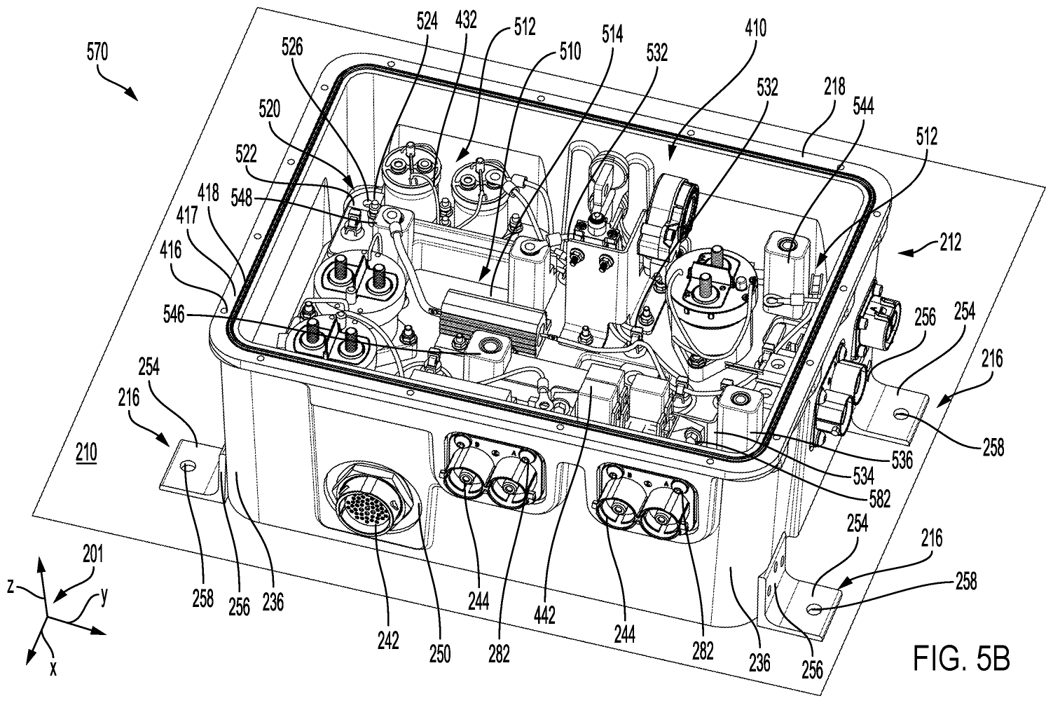

Turning to FIG. 5A, a fourth view 500 of a shelf 510 that may be inserted into and fastened to the housing 212 is shown. The fourth view 500 is top perspective view. The shelf 510 and components coupled to the shelf 510 is shown in fourth view 500 isolated from the housing 212. Similar to the housing 212 as described above, the shelf 510 may comprise material that is moldable, such as aluminum.

The interior 410, with reference to FIG. 4, may act as a receptacle for the shelf 510. The shelf 510 may act as the second layer described previously. The shelf 510 may separate the spaces of the interior 410 enclosed by the housing 212, with reference to FIG. 4, into the first space and a second space. The second space of the housing 212 may enclose a plurality of high voltage components 512, such as contactors, fuses, resistors, a single or plurality of safety switches, relays transducers, current sensors, BMSs, and/or the like. The second space may be located above and at a surface 514 of the shelf 510. In one or more examples, surface 514 may be a top surface of the shelf 510. The shelf 510 and surface 514 may act as a second level for the second space of the interior 410. The high voltage components 512 may be fastened to surface 514, in some examples.

The shelf 510 may have a plurality of holes, such as a first hole 516, a second hole 517, and a third hole 518. The first hole 516, the second hole 517, and the third hole 518 may be rectangular in shape with beveled edges and smoothed corners. The first hole 516, the second hole 517, and the third hole 518 may be open to the first space and the low voltage components 412.

The shelf 510 may have a plurality of corners 520. In one or more examples, there may be four of corners 520. The corners 520 may be complementary to the interior corners 420 of the interior 410 of FIG. 4. Each of the corners 520 may form an interface section 522. Each of the interface sections 522 may rest upon and be supported by the surfaces 424 of the protrusions 422. The each of the interface sections 522 may have a surface 524 and a through hole 526. Each of the interface sections 522 may further be depressed relative to surface 514 of shelf 510.

The each of the surfaces 524 and through holes 526 may be complementary to and support a fastener. Each of the aforementioned fasteners may extend and/or be threaded though the through holes 526 and into the holes 426 of protrusions 422 with reference to FIG. 4. The extending and/or threading the fasteners through the through holes 526 and holes 426 may fasten the interface sections 522 to the surfaces 424, therein fastening the shelf 510 to the protrusions 422. The molded protrusions within the interior of the housing as herein described may be molded at the same time as the housing and may allow for easy installation of the shelf thereon.

The fourth wires 438 may be electrically and/or communicatively couple the high voltage components 512. The fourth wires 438 may be threaded through and supported a plurality of mounts 532. The mounts 532 may be fastened or joined to the surface 514 of the shelf 510. The fourth wires 438 may act as ground wires and ground the high voltage components 512 and low voltage components 412 with reference to FIG. 4.

A mount platform 534 may be fastened to surface 514 via a first column 536 and a fastener 538. The mount platform 534 may have a surface 540 that may be formed on a plane perpendicular to the surface 514. The mount platform 534 and surface 540 may be formed from the first column 536. A platform 542 may be formed of mount platform 534. The platform 542 may abut surface 514. The upper surface and lower surface of platform 542 may be positioned as to be parallel with a plane the surface 514 may be coplanar with. Fastener 538 may be threaded through complementary holes that extend through the platform 542 and surface 514. When threaded through the complementary holes, fastener 538 may fasten the platform 542 to surface 514.

A second column 544, a first mount structure 546, and a second mount structure 548 may be fastened or joined to surface 514 of the shelf 510.

Turning to FIG. 5B a fifth view 570 of the shelf 510 and high voltage components 512 inserted into and partially enclosed by the interior 410 of the housing 212 is shown. The fifth view 570 is a top perspective view.

The fifth view 570 shows an example of the interface sections 522 resting on and being supported by surfaces 424 of FIG. 4. The component 442 may be mounted to surface 540 of the mount 532, with reference to FIG. 5A. Component 442 may be fit to and extend through third hole 518. A plurality of seventh fasteners 582 may fasten component 442 mount 532.

The first wires 432 may communicatively and/or electrically couple the high voltage components 512 to the low voltage components 412, with reference to FIG. 4. Likewise, fourth wires 438 may electrically couple the first the high voltage components 512 and low voltage components 412. The fourth wires 438 may act as ground wires for the high and low voltage components 512, 412.

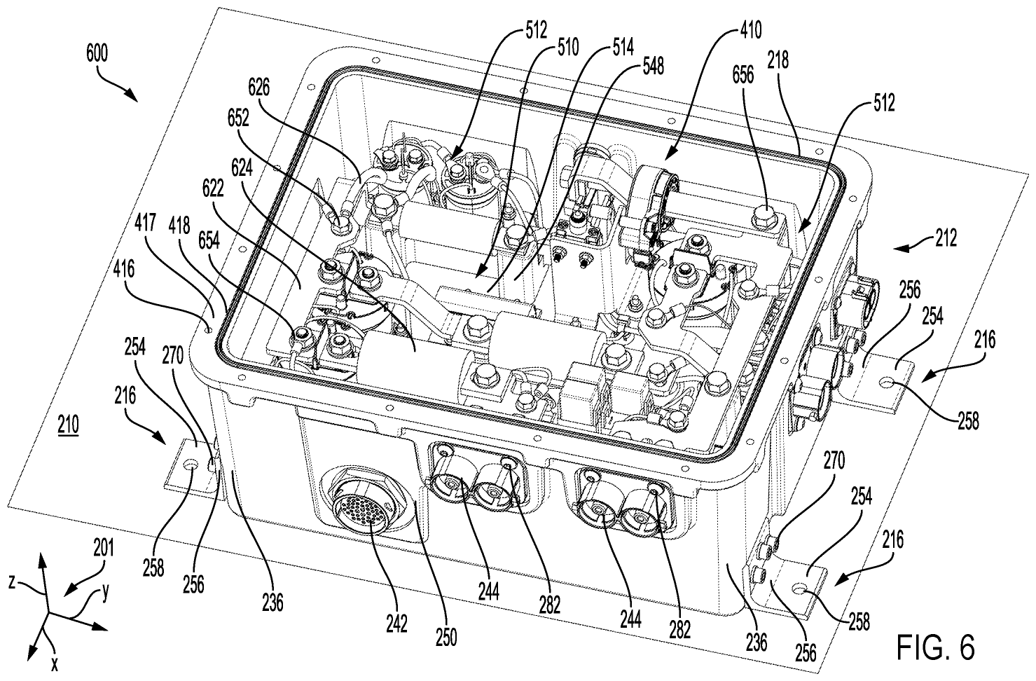

Turning to FIG. 6, a sixth view 600 of the junction box 202 is shown. The sixth view 600 may be a perspective view similar to that of FIG. 5B. As noted, the sixth view 600 shows the shelf 510 and high voltage components 512 inserted into and partially enclosed by the interior 410 of the housing 212. The sixth view 600 further shows a plurality of bus bars 622 and a plurality of fuses 624 that may be mounted above the shelf 510 and partially enclosed by the interior 410. Additionally, there may be a plurality of fifth wires 626 that may electrically and/or communicatively couple high voltage components 512 to the bus bars 622 and/or the fuses 624. The fifth wires 626 may be cabling, in some examples.

The plurality of bus bars 622 may be mounted to the high voltage components 512, the second column 544, the first mount structure 546, and/or the second mount structure 548. A plurality of fuses 624 may be mounted to components fastened or joined to the shelf 510. Some of the fuses 624 may be mounted to the first mount structure 546 and/or the second mount structure 548. One of the fuses 624 may be mounted between the high voltage components 512 and one of the bus bars 622. A plurality of eighth fasteners 652, a plurality of ninth fasteners 654, and a plurality of tenth fasteners 656 may be fastened to the bus bars 622.

Turning to FIG. 7, a seventh view 700 of the junction box 202 is shown. The seventh view 700 of junction box 202 may be a cross-sectional view taken along the dashed line 7-7 of FIG. 3.

The seventh view 700 shows the interior 410, which may be divided into a first space 712 and a second space 714 by the shelf 510 (also herein referred to as a first volume and a second volume). In one or more examples, the first space 712 may be located below the second space 714. The first space 712 may be located between the shelf 510 and a base 730 formed from the interior 410. The second space 714 may be located between the shelf 510 and the cover 214.

Though the disclosure shows the interior divided into two spaces, in one or more examples, it is possible for the interior to be divided into further spaces without departing from the scope of the present disclosure.

The base 730 of housing 212 may comprise a plurality of contiguous surfaces formed from the interior 410 of the housing 212. In one or more examples, the base 730 of housing 212 may include a first surface 732 and a second surface 734. The first surface 732 may be positioned on plane that is substantially or approximately parallel with and located below the second surface 734. For this example, the planes that are approximately parallel with the surface 210. Both the first surface 732 and second surface 734 may be approximately flat. The first surface 732 may be located below the second surface 734. The junction box according to the present disclosure comprises a shelf 510 coupled within the housing 212, the shelf 510 dividing a first level and a second level of the housing 212.

Continuing, the low voltage components 412 may be positioned within the first space 712 of the junction box, where the low voltage components 412 may be fastened to and include a plurality of boards, such as a printed circuit board (PCB) 744. The PCB 744 may be fastened and mounted to a plurality of supports 736. The supports 736 may be approximately cylindrical and fastened or joined to the base 730. In one or more examples, the supports 736 may be fastened or joined to the first surface 732. The centerlines of each of the supports 736 may be aligned with the base 730, such that the centerlines of the supports 736 may be normal to the first and second surfaces 732, 734.

The high voltage components 512 are further shown positioned within the second space 714 of the housing 212. In this way, the junction box, according to the present disclosure, comprises a multi-level housing in which high voltage components and low voltage components are positioned on separate levels. As shown, the high voltage components 512 may be coupled to a top surface of the shelf 510, while the low voltage components 412 are positioned in the first space 712 below a bottom surface of the shelf 510. As such, the first level (e.g., the first space 712) may be a low voltage level and the second level (e.g., the second space 714) may be a high voltage level. As is shown in FIG. 7, the first space 712 may comprise a smaller volume than the second space 714.

Via the multi-level housing junction box according to the present disclosure, the technical effect of providing sufficient space to enclose and separate electrical components while maintaining a relatively small footprint for the junction box is achieved. The relatively small footprint of the junction box may allow the junction box to be installed in relatively small packaging spaces even with an increased amount of components therein. Further, the multi-level junction box as herein described may reduce demand for manufacture of an unconventionally shaped or otherwise more complex junction box in the instance of demand for additional components, either within the junction box or to reduce degradation of the components within the junction box.

The seventh view 700 and the lateral cut may show a plurality of through holes 752 that extend through the cover 214. The through holes 752 may have a centerline normal to the surface 222. The through holes 752 may be fit and complementary to the first fasteners 224. The through holes 752 may act as the holes of the cover 214 complementary to the fasteners 224 described for FIG. 2.

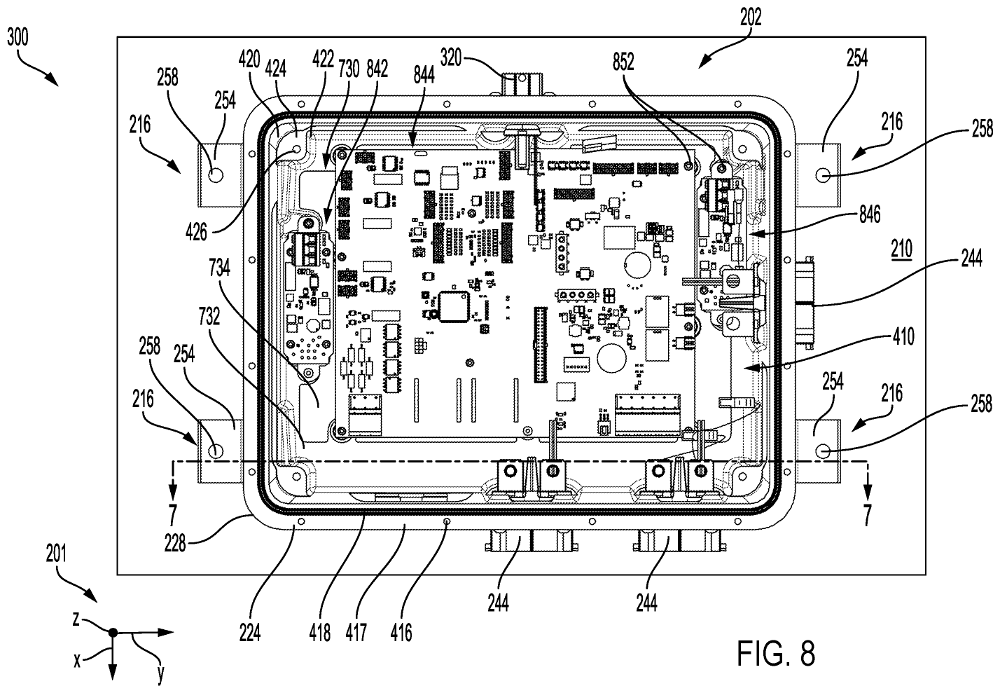

Turning to FIG. 8, the second view 300 of the junction box 202 is again shown, wherein the cover 214, the first port 242, and third port 246 are removed from the housing 212. Additionally, the surface 414 and platform 415 are removed from the interior 410 in FIG. 8.

View 300 shows the base 730 of the housing 212. View 300 shows the first surface 732 may be a non-uniform shape and be located about the perimeter of the second surface 734.

The base 730 may support and act as a mount for a plurality of PCBs. The PCBs may be fastened to the first surface 732 and fixed partially above the second surface 734. There may be a first PCB 842, a second PCB 844, and a third PCB 846. The second PCB 844 may be the PCB 744 of FIG. 7. The first PCB 842, second PCB 844, and third PCB 846 may be used in conjunction to control a battery monitoring system and/or a plurality of transducers that may be communicatively coupled with the low voltage components 412 and junction box 202. The first PCB 842, second PCB 844, and third PCB 846 may each be fastened to supports 736 via a plurality of fasteners 852.

The disclosure also provides support for a junction box for a vehicle, comprising: a housing, and a shelf coupled within the housing, the shelf dividing a first level and a second level of the housing. In a first example of the system, the second level is positioned vertically above the first level. In a second example of the system, optionally including the first example, a plurality of electrical components are positioned in the junction box, the plurality of electrical components including low voltage components and high voltage components. In a third example of the system, optionally including one or both of the first and second examples, the system further comprises: low voltage components positioned in the first level and high voltage components positioned in the second level. In a fourth example of the system, optionally including one or more or each of the first through third examples, the shelf is positioned on top of protrusions formed into walls of the housing. In a fifth example of the system, optionally including one or more or each of the first through fourth examples, the first level includes a volume defined by a bottom surface of the shelf, a base of the housing, and side walls of the housing. In a sixth example of the system, optionally including one or more or each of the first through fifth examples, the second level includes a volume defined by a top surface of the shelf, a cover of the housing, and side walls of the housing. In a seventh example of the system, optionally including one or more or each of the first through sixth examples, the first level of the housing is smaller in volume than the second level of the housing. The disclosure also provides support for a junction box for a vehicle, comprising: a multi-level housing including a low voltage level and a high voltage level, and a plurality of fasteners configured to couple the junction box to the vehicle. In a first example of the system, the low voltage level is positioned vertically below the high voltage level, wherein low voltage electrical components are positioned in the low voltage level, and wherein the low voltage electrical components include one or more components coupled to a base of the multi-level housing. In a second example of the system, optionally including the first example, the system further comprises: a shelf positioned in the multi-level housing, the shelf separating the low voltage level from the high voltage level, and wherein the shelf comprises. In a third example of the system, optionally including one or both of the first and second examples, the multi-level housing is rectangular in shape, and wherein there are protrusions molded into each corner of the multi-level housing, the protrusions configured to support a shelf. In a fourth example of the system, optionally including one or more or each of the first through third examples, the system further comprises: a shelf positioned in the multi-level housing, the shelf including high voltage electrical components coupled to the shelf. In a fifth example of the system, optionally including one or more or each of the first through fourth examples, the multi-level housing and a shelf coupled within the multi-level housing comprise aluminum. The disclosure also provides support for a junction box for a vehicle, comprising: a housing configured to separate low voltage electrical components and high voltage electrical components onto different vertical levels within the housing, the low voltage electrical components coupled to different surfaces of the junction box than the high voltage electrical components. In a first example of the system, the low voltage electrical components are coupled to a base of the housing, and wherein the high electrical components are not coupled to the base of the housing. In a second example of the system, optionally including the first example, the system further comprises: a shelf coupled within an interior of the housing, wherein a first volume below the shelf within the housing is a first level, wherein the low voltage electrical components are positioned within the first level, and wherein a second volume above the shelf within the housing is a second level, wherein the high voltage electrical components are positioned within the second level. In a third example of the system, optionally including one or both of the first and second examples, the high voltage electrical components are pre-assembled onto a shelf positioned within the housing. In a fourth example of the system, optionally including one or more or each of the first through third examples, the system further comprises: a cover that is removably coupled to the housing. In a fifth example of the system, optionally including one or more or each of the first through fourth examples, a first level comprises the low voltage electrical components, and wherein a second level comprises the high voltage electrical components, the first level positioned vertically below the second level.

In another representation, it is noted that other configurations for coupling the electrical components within the housing of the junction box are possible without departing from the scope of the present disclosure. For example, one or more of the electrical components may be coupled to an interior-facing surface of the cover of the junction box. Additionally, or alternatively, electrical components may be coupled to an underside of the shelf. In such examples, high voltage components may be coupled to one side of the shelf (e.g., a top side), while low voltage components may be coupled to an opposite side of the shelf (e.g., an underside, also referred to as a bottom of the shelf).

FIGS. 2-8 are drawn to scale, although other relative dimensions may be used. FIGS. 1-8 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example.

It is to be understood that the invention may assume various alternative orientations and step sequences, except where expressly specified to the contrary. It is also to be understood that the assemblies, devices, and methods illustrated in the attached drawings, and described in the following specification are simply exemplary embodiments of the inventive concepts. Hence, specific dimensions, directions, or other physical characteristics relating to the embodiments disclosed are not to be considered as limiting, unless expressly stated otherwise.

It will be appreciated that the configurations disclosed herein are exemplary in nature, and that these specific examples are not to be considered in a limiting sense, because numerous variations are possible. The subject matter of the present disclosure includes all novel and non-obvious combinations and sub-combinations of the various systems and configurations, and other features, functions, and/or properties disclosed herein. As used herein, the terms “approximately” and “substantially” are construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

The foregoing description is considered as illustrative only of the principles of the invention. Further, since numerous modifications and changes will readily occur to those skilled in the art, it is not desired to limit the invention to the exact construction and processes shown and described herein. Accordingly, all suitable modifications and equivalents may be considered as falling within the scope of the invention as defined by the claims which follow.

1. A junction box for a vehicle, comprising:
a housing; and
a shelf coupled within the housing, the shelf dividing a first level and a second level of the housing.

2. The junction box of claim 1, wherein the second level is positioned vertically above the first level.

3. The junction box of claim 1, wherein a plurality of electrical components are positioned in the junction box, the plurality of electrical components including low voltage components and high voltage components.

4. The junction box of claim 1, further comprising low voltage components positioned in the first level and high voltage components positioned in the second level.

5. The junction box of claim 1, wherein the shelf is positioned on top of protrusions formed into walls of the housing.

6. The junction box of claim 1, wherein the first level includes a volume defined by a bottom surface of the shelf, a base of the housing, and side walls of the housing.

7. The junction box of claim 1, wherein the second level includes a volume defined by a top surface of the shelf, a cover of the housing, and side walls of the housing.

8. The junction box of claim 1, wherein the first level of the housing is smaller in volume than the second level of the housing.

9. A junction box for a vehicle, comprising:
a multi-level housing including a low voltage level and a high voltage level; and
a plurality of fasteners configured to couple the junction box to the vehicle.

10. The junction box of claim 9, wherein the low voltage level is positioned vertically below the high voltage level, wherein low voltage electrical components are positioned in the low voltage level, and wherein the low voltage electrical components include one or more components coupled to a base of the multi-level housing.

11. The junction box of claim 9, further comprising a shelf positioned in the multi-level housing, the shelf separating the low voltage level from the high voltage level.

12. The junction box of claim 9, wherein the multi-level housing is rectangular in shape, and wherein protrusions are molded into each corner of the multi-level housing, the protrusions configured to support a shelf.

13. The junction box of claim 9, further comprising a shelf positioned in the multi-level housing, the shelf including high voltage electrical components coupled to the shelf.

14. The junction box of claim 9, wherein the multi-level housing and a shelf coupled within the multi-level housing comprise aluminum.

15. A junction box for a vehicle, comprising:
a housing comprising a plurality of levels, the housing configured to separate low voltage electrical components and high voltage electrical components onto different vertical levels within the housing, the low voltage electrical components coupled to different surfaces of the junction box than the high voltage electrical components.

16. The junction box of claim 15, wherein the low voltage electrical components are coupled to a base of the housing, and wherein the high voltage electrical components are not coupled to the base of the housing.

17. The junction box of claim 15, further comprising a shelf coupled within an interior of the housing, wherein a first volume below the shelf within the housing is a first level of the plurality of levels, wherein the low voltage electrical components are positioned within the first level, and wherein a second volume above the shelf within the housing is a second level of the plurality of levels, wherein the high voltage electrical components are positioned within the second level.

18. The junction box of claim 15, wherein the high voltage electrical components are pre-assembled onto a shelf positioned within the housing.

19. The junction box of claim 15, further comprising a cover that is removably coupled to the housing.

20. The junction box of claim 15, wherein a first level comprises the low voltage electrical components, and wherein a second level comprises the high voltage electrical components, the first level positioned vertically below the second level.
